(19) United States
(12) Patent Application Publication
(10) Pub. No.: US 2025/0316518 A1
(43) Pub. Date: Oct. 9, 2025

(54) System and Method for Orienting a Bonding Head

(71) Applicant: CANON KABUSHIKI KAISHA, Tokyo (JP)

(72) Inventor: Nilabh K. Roy, Cedar Park, TX (US)

(21) Appl. No.: 18/625,387

(22) Filed: Apr. 3, 2024

(51) Int. Cl. H01L 21/68; H01L 21/67; H01L 23/00

(52) U.S. Cl. CPC H01L 21/681; H01L 21/67092; H01L 24/80; H01L 2224/80009; H01L 2224/80125; H01L 2224/80896

(57) ABSTRACT

A bonding system configured to bond a chiplet to a destination site and method of using the bonding system. The bonding system comprises a bonding head configured to hold the chiplet and a microscope. The microscope is configured to: generate a first image of a first subset of the plurality of chiplet bonding pads with the microscope in a first state; and generate a second image of a second subset of the plurality of chiplet bonding pads with the microscope in a second state. The bonding system may also comprise a processor configured to estimate a first orientation of the chiplet based on the first image and the second image. The bonding system may also comprise a positioning system configured to adjust the chiplet and the destination site relative to each other based on the first orientation. The bonding head is configured to bond the chiplet to the destination site.

### TECHNICAL FIELD

The present disclosure relates to systems and methods of aligning bonding pads with bonding locations. In particular, the present disclosure relates to systems and methods of adjusting an alignment system based on the component that is to be aligned.

### DESCRIPTION OF THE RELATED ART

The manufacture of devices (such as electronic devices) that include multiple components (chiplet) requires that these multiple components be bonded together. One method of bonding these components includes aligning a first set of electrical pads (interconnect contacts) on a first chiplet with a second set of electrical pads with a second chiplet. It is preferential that the systems and methods that do this alignment have an accuracy that is a fraction ( 1/10 to ¼) of the pad diameters. It is also preferential that this alignment be performed at a very high speed (less than a second or even much faster). Current methods of accomplishing this task include using alignment features on the chiplets to be bonded.

In recent times the size of the chiplets and pads are decreasing while the density of the pads is also increasing. What is needed is a fast and accurate method of aligning pads without alignment features.

### SUMMARY OF THE INVENTION

A first embodiment, may be a bonding system configured to bond a first chiplet to a first destination site. The first chiplet may have a plurality of chiplet bonding pads. The first destination site has a first plurality of destination bonding pads. The bonding system comprises a first bonding head configured to hold the first chiplet. The bonding system also comprises a microscope. The microscope is configured to: generate a first image of a first subset of the plurality of chiplet bonding pads with the microscope in a first state; and generate a second image of a second subset of the plurality of chiplet bonding pads with the microscope in a second state. The bonding system may also comprise a processor configured to estimate a first orientation of the first chiplet based on the first image and the second image. The bonding system may also comprise a positioning system configured to adjust the first chiplet and the first destination site relative to each other based on the first orientation. The first bonding head is configured to bond the first chiplet to the first destination site.

In an aspect of the first embodiment the microscope may comprise: a sensor; a first optical subsystem configured to receive light from the first chiplet; a second optical subsystem configured to transmit light towards the sensor; and a rotatable optical element located between the first optical subsystem and the second optical subsystem configured to be at a first angle when the microscope is in the first state and configured to be at a second angle when the microscope is in the second state.

In an aspect of the first embodiment a first acceptance angle of the first optical subsystem while at a working distance from the first chiplet may receive light from both the first subset of the plurality of chiplet bonding pads and the second subset of the plurality of chiplet bonding pads. The sensor may be located at a focal plane of the second optical subsystem while the microscope is in the first state and the second state. The sensor may receive light representative of the first image while not receiving light representative of the second image when the microscope is in the first state. The sensor may receive light representative of the second image while not receiving light representative of the first image when the microscope is in the second state.

In an aspect of the first embodiment, a front focal plane of the first optical subsystem may be within a depth of focus distance from and parallel to an average plane of the plurality of chiplet bonding pads when held by the first bonding head.

In an aspect of the first embodiment, a front focal plane of the first optical subsystem may be within a depth of focus distance from and parallel to an average plane of the plurality of chiplet bonding pads when held by the first bonding head.

In an aspect of the first embodiment, a focal plane of the second optical subsystem may be within a depth of focus distance from and parallel to a plane of the sensor.

In an aspect of the first embodiment, a center of rotation of the rotatable optical element may be within a threshold distance from a back focal plane of the first optical subsystem.

In an aspect of the first embodiment, a center of rotation of the rotatable optical element is within a threshold distance from a front focal plane of the second optical subsystem.

In an aspect of the first embodiment, the first optical subsystem may include a first subordinate optical system configured to receive light from a first sensing region above the first bonding head. The first optical subsystem may also include a second subordinate optical system configured to receive light from a second sensing region above a second bonding head. The first optical subsystem may also include an optical combiner configured to: receive light from the first subordinate optical system and the second subordinate optical system; and transmit light to the rotatable optical element.

In an aspect of the first embodiment, the optical combiner may include one or more of: an illumination system that illuminates both the first sensing region and the second sensing region; and an optical switch that alternatively receives light from either the first sensing region and the second sensing region; and guides the received light towards the rotatable optical element.

In an aspect of the first embodiment the optical combiner may include one or more of: an illumination system that alternatively illuminates the first sensing region and the second sensing region; and a beam combiner that receives light from both the first sensing region and the second sensing region; and guides the received light towards the rotatable optical element.

A second embodiment, may be a bonding method employing a bonding system configured to bond a first chiplet to a first destination site, wherein the first chiplet has a plurality of chiplet bonding pads, wherein the first destination site has a first plurality of destination bonding pads, the bonding method comprising holding the first chiplet with a first bonding head. The bonding method also comprises generating a first image of a first subset of the plurality of chiplet bonding pads with a microscope in a first state. The bonding method also comprises generating a second image of a second subset of the plurality of chiplet bonding pads with the microscope in a second state. The bonding method also comprises estimating a first orientation of the first chiplet based on the first image and the second image. The bonding method also comprises adjusting the first chiplet and the first destination site relative to each other with a positioning system based on the first orientation. The bonding method also comprises bonding the first chiplet to the first destination site with the bonding head.

The second embodiment may further comprise shifting the microscope from the first state to the second state by rotating a rotatable optical element. The optical element is positioned between a first optical subsystem and a second optical subsystem. The first optical subsystem is configured to receive light from the first chiplet. The second optical subsystem is configured to transmit light towards the sensor.

The second embodiment may further comprise: receiving, by the first optical subsystem while at a working distance from the first chiplet, light from both the first subset of the plurality of chiplet bonding pads and the second subset of the plurality of chiplet bonding pads; and receiving, by the sensor located at a focal plane of the second optical subsystem while the microscope is in the first state. light representative of the first image and not the second image.

The second embodiment may further comprise adjusting a relative position of the first bonding head and a front focal plane of the first optical system so that an average plane of the plurality of chiplet bonding pads when held by the first bonding head is within a depth of focus distance of the first optical system.

The second embodiment may further comprise adjusting a relative position of a focal plane of the second optical system to be within a depth of focus distance from and parallel to a plane of the sensor.

The second embodiment may further comprise receiving light from a first sensing region above the first bonding head with a first subordinate optical system of the first optical subsystem. The second embodiment may further comprise receiving light from a second sensing region above a second bonding head with a second subordinate optical system of the first optical subsystem. The second embodiment may further comprise receiving light from the first subordinate optical system and the second subordinate optical system with an optical combiner of the first optical subsystem. The second embodiment may further comprise transmitting light to the rotatable optical element with the optical combiner.

The second embodiment, may further comprise switching between illuminating the first sensing region and the second sensing region with an illumination system of the optical combiner. The second embodiment, may further comprise receiving light from both the first sensing region and the second sensing region with a beam combiner of the optical combiner. The second embodiment, may further comprise guiding the received light the received light towards the rotatable optical element with the beam combiner.

The second embodiment, may further comprise illuminating both the first sensing region and the second sensing region with an illumination system of the optical combiner. The second embodiment, may further comprise receiving light from both the first sensing region and the second sensing region with an optical switch of the optical combiner. The second embodiment, may further comprise switching between guiding light from either the first sensing region and the second sensing region towards the rotatable optical element with the beam combiner with the optical switch.

The second embodiment, may further comprise estimating a first x-y shift of the first image relative to a first reference image. The second embodiment may further comprise estimating a second x-y shift of the second image relative to a second reference image. Estimating the first orientation may include estimating a rotation error of the first chiplet based on the first x-y shift and the second x-y shift. The second embodiment may further comprise holding a destination substrate having a destination site. The second embodiment may further comprise adjusting a relative position of the chiplet and the destination site based on both the first x-y shift, second x-y shift, and the rotation error.

In an aspect of the second embodiment, the first and second subsets of the plurality of chiplet bonding pads each include a unique arrangement of chiplet bonding pads relative to the plurality of chiplet bonding pads.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF THE FIGURES

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention and are therefore not to be considered limiting of its scope, for the invention may admit to other equally effective embodiments.

FIG. 1 is an illustration of an exemplary bonding system in which an embodiment may be used.

FIGS. 2A-B are illustrations of an exemplary bonding head that may be used in an embodiment.

FIG. 3 is an illustration of a bonding method that may be used in an embodiment.

FIGS. 4A-B are illustrations of two states of a microscope that may be used in an embodiment.

FIGS. 5A-B are illustrations of microscopes that may be used in an embodiment.

FIG. 6 is a flowchart illustrating an alignment setup process and a contacts measuring step as may be used in an embodiment.

FIG. 7 is an illustration of an image relative to a reference that may be used in an embodiment.

Throughout the figures, the same reference numerals and characters, unless otherwise stated, are used to denote like features, elements, components, or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

The following describes certain explanatory embodiments. Other embodiments may include alternatives, equivalents, and modifications. Additionally, the explanatory embodiments may include several features, and a particular feature may not be essential to some embodiments of the devices, systems, and methods. Furthermore, some embodiments may include features from two or more of the following explanatory embodiments.

As used herein, the conjunction “or” generally refers to an inclusive “or,” though “or” may refer to an exclusive “or” if expressly indicated or if the context indicates that the “or” must be an exclusive “or.” And, as used herein, the terms “first,” “second,” and so on, do not necessarily denote any ordinal, sequential, or priority relation and may be used to more clearly distinguish one member, operation, element, group, collection, set, etc. from another without expressing any ordinal, sequential, or priority relation.

### Bonding System

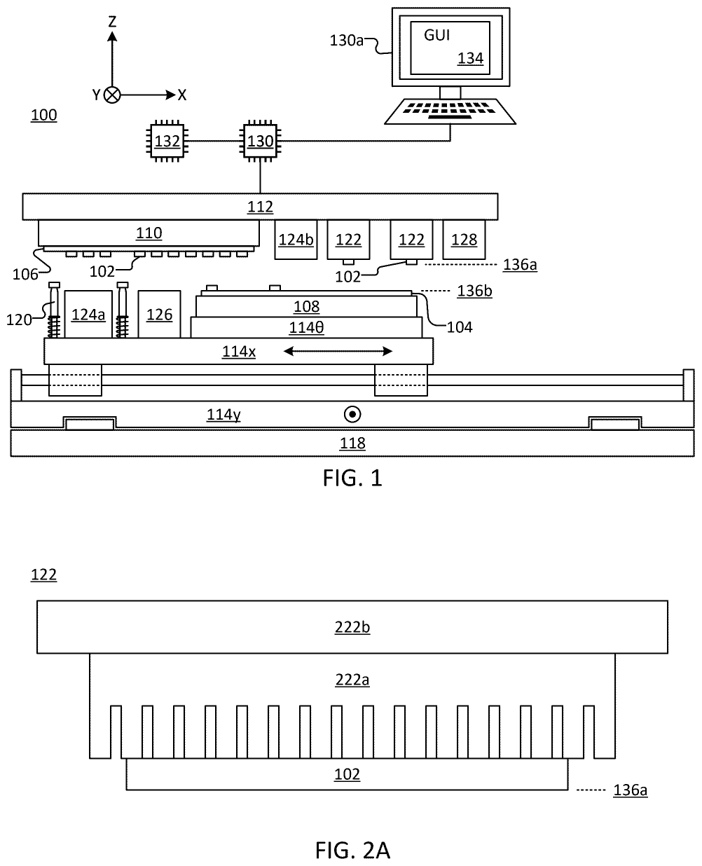

FIG. 1 is an illustration of some components of a bonding system 100 which may be used to bond a chiplet 102 to a substrate 104. The chiplet 102 is a component that includes a chiplet set of interconnect contacts 202a on a chiplet bonding surface 136a. The chiplet may have widths and heights on the order 0.5 mm to 30 mm and a thickness between 5-800 μm. The substrate 104 also includes a substrate set of interconnect contacts 202b on a substrate bonding surface 136b. The chiplet set of interconnect contacts 202a and the substrate set of interconnect contacts 202b will in general be referred to as interconnect contacts 202 which provide a plurality of connections between the chiplet 102 and the substrate 104. In an embodiment, these plurality of interconnect contacts 202 provide electrical connections between the chiplet 102 and the substrate 104. In an alternative embodiment, the plurality of interconnect contacts 202 provide one or more of fluid connections, optical connections, and electrical connections. During the bonding process it is very important that the chiplet set interconnect contacts 202a and the substrate set of interconnect contacts 202b be aligned with each other. This becomes increasingly difficult as the size of each interconnect contact 202 and the density of the plurality of interconnect contacts 202 increases. Each interconnect contact 202 may be made of an electrically conductive material such as copper. Each interconnect contact 202 may be flush with the surface of the chiplet 102 or substrate 104 or dished nanometers below the surface of the chiplet 102 or substrate 104. The surface of the chiplet 102 or substrate 104 may be a dielectric material such as silicon oxide or silicon nitride with interconnect contacts 202 dished nanometers below the plane of the dielectric.

In an embodiment, the chiplet 102 may have a small geometric shape (for example a rectangle or other polygon) and may have a planar dimension that is between 0.5 mm to 30 mm and may have a thickness of less than 1 mm (for example 0.8 to 0.01 mm). The chiplet 102 may have been singulated from a larger substrate such as a semiconductor wafer, which may have been subjected to a thinning process. The chiplet 102 will typically carry a set of integrated electronic components and circuits formed on it by patterning, coating, etching, doping, plating, singulating, etc. The chiplet 102 will typically have electrical functions such as: memory, logic, field programmable gate arrays (FPGA), accelerator circuits, application-specific integrated circuits (ASICs), security co-processors, graphics processing units (GPUs), machine learning circuits, specialized processors, controllers, devices, electrical circuits, arrays of passive components, etc. The chiplet 102 may also be a MEMS device, an optical device, an electrical-optical device, etc. The chiplet 102 may be any device that has a set of interconnect contacts 202a.

In an embodiment the substrate 104 is a patterned semiconductor wafer that has a substrate set of interconnect contacts 202b. The substrate set of interconnect contacts 202b may provide connections to components within the substrate 104 or mounted onto the substrate 104. The substrate 104 may have a plurality of bonding locations for the chiplet 102 and also for other chiplets different from the chiplet 102. The substrate 104 may already have chiplets that are identical and/or different from chiplet 102 bonded to the substrate 104. The substrate set of interconnect contacts 202b may be on a chiplet bonded to the substrate 104. In an alternative embodiment, the substrate 104 is not a patterned semiconductor wafer but does have a substrate set of interconnect contacts 202b.

FIG. 1 illustrates a plurality of chiplets 102 temporarily attached to a transfer substrate 106. The substrate 104 is held by a substrate chuck 108. The transfer substrate 106 is held by a transfer chuck 110. In an embodiment, the transfer chuck 110 is mounted to a bridge 112 opposite the substrate chuck 110. In an alternative embodiment, the transfer chuck 110 is mounted adjacent to the substrate chuck 110. In an embodiment, the transfer substrate 106 is a tape frame and the transfer chuck 110 is adapted for mounting a tape frame and helping with the release of the chiplet 102 from the tape frame. In an alternative embodiment, the transfer substrate is a reel on which the chiplet 102 is mounted and the transfer chuck 110 is a reel feeder. In an alternative embodiment, the transfer substrate 106 is a tray with pockets for holding the chiplet 102 in each pocket and the transfer chuck 110 is a tray holder.

The bonding system 100 may include or be in communication with one or more robots (not shown) for loading the transfer substrate 106 on and off the transfer chuck 110 and the substrate 104 on and off the substrate chuck 108. An example of such a robot is commonly referred to as equipment front end module (EFEM) which includes robots for transferring substrates of a variety of types between ultra clean storage containers such as a front opening unified pod (FOUP).

The substrate chuck 108 may be mounted to a substrate stage 114. The substrate stage 114 may provide a single axis or multiple axis (for example 6) of motion control with mm scale to sub-mm accuracy over a limited range. The substrate stage 114 may be a highly accurate X-Y-Z-θ stage combined with a light interferometry measurement system so that the absolute position can be repeatedly achieved high accuracy. In an embodiment, the substrate stage 114 may include: a substrate rotation stage 1140; a substrate x motion stage 114x; a substrate y motion stage 114y; and possibly other stages (for example tip and tilt).

The bonding system 100 may include one or more transfer heads 120 that may be used in parallel. Each transfer head 120 is used to transfer a chiplet 102 to a bonding head 122. In an embodiment, the transfer head 120 may include a chiplet chuck that is a vacuum type suction nozzle that can be moved in at least the direction towards the transfer chuck 110 by one or more actuators. The tip of the suction nozzle may be smaller than the chiplet 102. In an alternative embodiment, the transfer head 120 may include a chiplet chuck for holding the chiplet 102 which may be but is not limited to: a Bernoulli chuck; a vacuum chuck; a pin-type chuck; a groove-type chuck; an electrostatic chuck; an electromagnetic chuck; a non-contact chuck; a PEEK plastic chuck; a suction cup; an edge gripping chuck; and/or the like. The transfer head 120 may include one or more actuators or stages such as voice coil motors, piezoelectric motors, linear motors, nut and screw motors, piezo-actuated stages, brushless DC motor stages, DC motor stages stepper motors, which are configured to move the chiplet chuck to and from the transfer substrate 106 and the bonding head 122 in for example the z-axis direction, and potentially other directions (for example x, y, θ (rotation about the z-axis), ψ(rotation about the x-axis), and φ-axes (rotation about the y-axis)).

The bonding system 100 may include or be in communication with a chiplet pretreatment system(s) (not shown). The pretreatment may include wet and/or dry chemical processes which prepare the surface of the chiplet 102 prior to bonding the chiplet 102 to the substrate 104. The pretreatment of the chiplet 102 may occur at any time prior to bonding the chiplet 102 to the substrate 104. For example, the pretreatment may occur prior to the chiplet 102 being loaded onto the transfer substrate 106. For example, the pretreatment may occur while the chiplet 102 is on the transfer substrate 106. For example, the pretreatment may occur while the chiplet 102 is on the transfer head 120. For example, the pretreatment may occur while the chiplet 102 is on the bonding head 122. For example, the pretreatment may occur after the chiplet 102 is on the transfer head 120 and prior to the chiplet 102 being loaded onto the bonding head 104.

The bonding system 100 includes an upward facing alignment system 124a. The upward facing alignment system 124a may be used to measure the position of the chiplet 102 on the bonding head 122. The bonding system 100 also includes a downward facing alignment system 124b that is used to measure a bonding location on the substrate 104. In an alternative embodiment, the upward facing alignment system 124a and downward facing alignment system 124b may be a single system that can measure both the chiplet 102 on the bonding head 122 and the bonding location on the substrate 104.

The bonding system 100 may include an upward facing imaging system 126 for inspecting chiplets 102 on the transfer substrate 106 and may also be used for inspecting chiplets on the bonding heads 122. The bonding system 100 may include a downward facing imaging system 128 for inspecting the substrate 104.

The bonding system 100 is regulated, controlled, and/or directed by one or more processors 130 (controller) in communication with one or more components and/or subsystems such as the substrate chuck 108, the transfer chuck 110, the substrate stage 114, the transfer head 120, bonding head 122, upward facing alignment system 124a, downward facing alignment system 124b, upward facing imaging system 126, downward facing imaging system 128. The processor 130 may operate based on instructions in a computer readable program stored in a non-transitory computer readable memory 132. The memory 132 may be distributed among multiple processors. The processor 130 may be or include one or more of a CPU, MPU, GPU, ASIC, FPGA, DSP, and one or more general-purpose computers. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. The processor 130 may include a plurality of processors that are both included in the bonding system 100 and in communication with the bonding system 100. The processor 130 may be in communication with a networked computer 130a on which analysis is performed and control files such as a drop pattern are generated. In an embodiment, there are one or more graphical user interface (GUI) 132 on one or both of the networked computer 140a and a display in communication with the processor 130 which are presented to an operator and/or user.

### Bonding Head

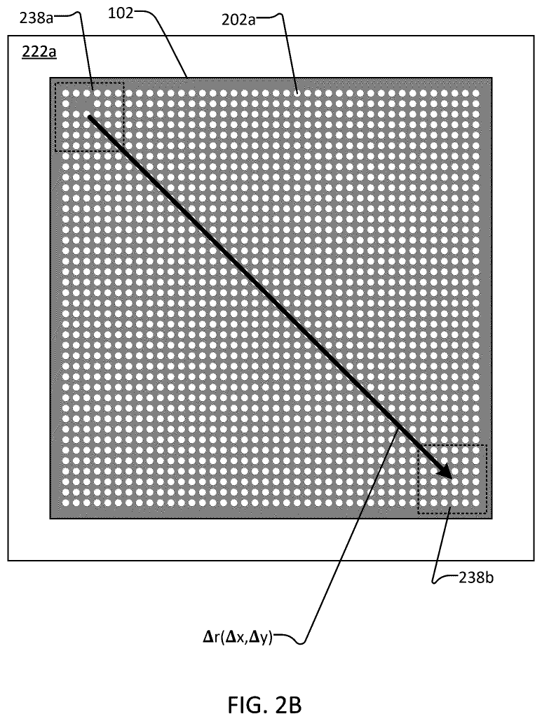

As illustrated in FIG. 1 the bonding system 100 includes one or more bonding head(s) 122. The bonding head 122 may be attached to the bridge 112. The bonding system 100 may include a plurality of bonding heads 122 which are used in parallel. The bonding head 122 is positioned opposite the substrate chuck 108. Each of the bonding heads 122 includes a chiplet chuck 222a and may include a chiplet stage 222b as illustrated in FIG. 2A. The chiplet chuck 222a is adapted to hold the chiplet 102 in a stable secure manner with position stability that is less than 1 μm, 0.1 μm, or 0.01 μm. The chiplet chuck 222a may be adapted to hold the back of the chiplet 102. In an alternative embodiment, the chiplet chuck 222a may be adapted to grip the edges of the chiplet 102. The chiplet chuck 222a may be: a vacuum chuck; a latch type chuck; an edge griping chuck; a pin-type chuck; a groove-type chuck; an electrostatic chuck; or an electromagnetic chuck.

The chiplet stage 222b is a motion stage for controlling the position of the chiplet chuck 222a relative to the bridge 112. The bonding head stage 222b provides motion control in one or more directions in for example the z-axis direction, and potentially other directions (for example x, y, θ, ψ, and φ-axes). The bonding head stage 222b may include one or more actuators or stages such as voice coil motors, piezoelectric motors, linear motors, nut and screw motors, piezo-actuated stages, brushless DC motor stages, DC stepper motors. The positioning accuracy of the bonding head stage 222b may be less than 100 nm, 10 nm or 1 nm. FIG. 2B is an illustration of a chiplet 102 on a chiplet chuck 222a showing a chiplet set of interconnect contacts 202a on the chiplet 102. As chiplets become more complex the number of interconnect contacts 202 increase and can be in the hundreds, thousands, tens of thousands, hundreds of thousands, even millions. The chiplet stage 222b may employ a highly accurate X-Y-Z-θ stage combined with a light interferometry system so that the absolute position can be repeatedly achieved with high accuracy.

### Chiplet

The chiplet 102 may be or include one or more of: a semiconductor device; a micro-electro-mechanical system (MEMS) device, micro-opto-electro-mechanical system (MOEMS) device; an optical device, an electro-optical device; a microfluidic device, a piezoelectric device, a thermoelectric device, a spintronic device, a superconducting device, a solar device; an organic electronic device; or any other device that is to precision bonded to another device. Each chiplet includes a chiplet set of interconnect contacts 202a. The chiplet set of interconnect contacts 202a are arranged on a chiplet bonding surface 136a of the chiplet in a pattern and are made of a different material from the rest of the chiplet bonding surface 136a. The chiplet set of interconnect contacts 202a may be made of a different material than a chiplet bonding surface 136a. The chiplet 102 may include an orientation feature such as an interconnect contact that is missing in a regular arrangement of interconnect contacts as illustrated in FIG. 2B.

The substrate 104 may also be a chiplet or include an arrangement of chiplets attached to it. The substrate 104 and the chiplet 102 may include alignment features.

### Bonding Method

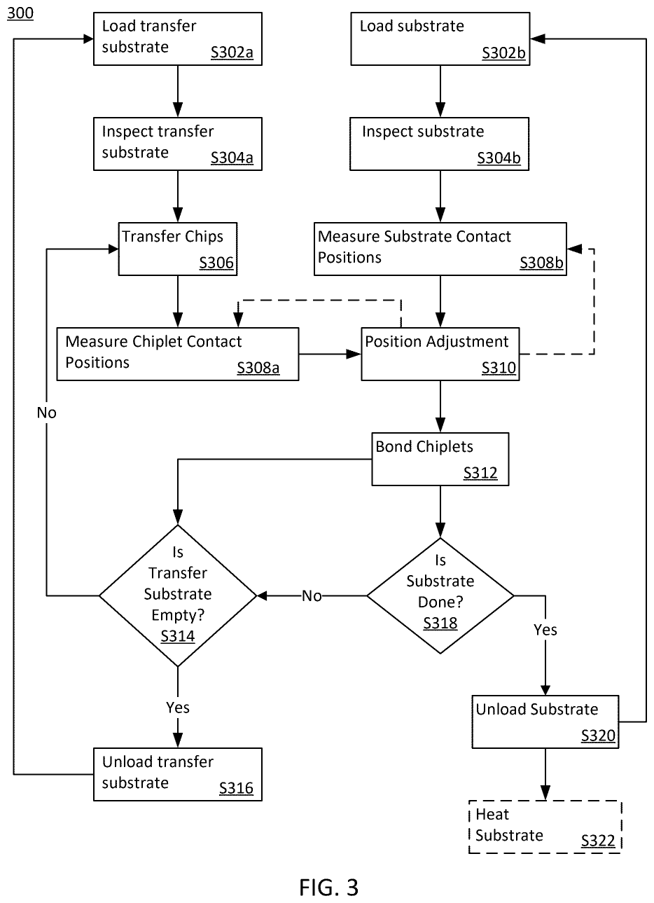

The bonding system 100 is used to bond a plurality of chiplets 102 onto a plurality of substrates 104 using a bonding method 300 such as the one illustrated in FIG. 3. Prior to the bonding method 300 being performed registration steps may be performed in which the substrate stage 114, the upward facing alignment system 124a, and the downward facing alignment system 124b are registered with each other. The bonding method 300 may include loading a transfer substrate 106 onto the transfer chuck 110 in a first loading step S302a. The bonding method 300 may include loading a substrate 104 onto the substrate chuck 104 in a second loading step S302b. One or more robots may be used in the loading steps S302(a, b). The one or more robots may be a wafer handling robot. The robot may be a chiplet feeding system or tray handler. The second loading step S302b may include standard lithography alignment techniques using standard alignment techniques and using alignment marks such as: moiré interference marks; one or more two-dimensional diffraction gratings; crosses, box in box, bar-in-bars, bullseyes, edge marks, serpentine marks, etc.

The bonding method 300 may include a first inspection step S304a of generating pictures of the transfer substrate S304a with an upward facing imaging system 126. The upward facing imaging system 126 may generate pictures of the transfer substrate 106 and the processors 130 will analyze those pictures to identify positions of the chiplets 102 on the transfer substrate 106. The bonding method 300 may include a second inspection step S304b of taking pictures of the substrate 106 with a downward facing imaging system 128. The upward facing imaging system 128 may generate pictures of the substrate 104 and the processors 130 will analyze those pictures to identify bonding positions on the substrate 104. The tilt of the substrate 104 on the substrate chuck 108 may also be measured.

The bonding method 300 may include a transfer step S306 in which one or more transfer heads 120 may transfer chiplets 102 from the transfer substrate 106 to the one or more bonding heads 122. The transfer step may be done with an accuracy that is within the positioning range of a chiplet stage 222b. In an alternative embodiment, the one or more bonding heads 122 retrieve one or more chiplets 102 directly from the transfer substrate 106. The approximate position of the chiplet on the bonding head may be measured using the upward facing imaging system 126.

The bonding method 300 may include a chiplet contacts position measuring step S308a in which the upward facing alignment system 124a measures the positions of the chiplet set of interconnect contacts 202a on each chiplet 102 relative to the chiplet chuck 222a on which it is mounted which is transmitted to the processors 130. The bonding method 300 may include a substrate contacts position measuring step S308b in which the downward facing alignment system 124b measures the positions of the substrate set of interconnect contacts 202b on the substrate relative to the substrate chuck 108 which is transmitted to the processors 130. In an alternative embodiment, a single alignment system 124 is used for measuring the chiplet set of interconnect contacts 202a on a chiplet 102 and substrate set of interconnect contacts 202b on the substrate 104, by having optics that guide light to and from the chiplet 102 and the substrate 104. In an embodiment, the substrate 102 has a plurality of bonding positions which are determined by the downward facing imaging system and/or information received by the processors 130 about the substrate 104.

The bonding method 300 may include a position adjustment step S310. The position adjustment step S310 includes processors 130 sending instructions to one or more chiplet stages 222b and/or the substrate stage 114 based on the alignment information gathered in the chiplet contacts position measuring step S308a; the substrate contacts position measuring step S308b; and information about the expected bonding position of each of the chiplets. The expected bonding position information on the substrate may be generated from the downward facing imaging system or from information about the substrate 104 generated by the processor from a database or a message from another processor on a network. The substrate stage 114 may include a stage position encoder that allows accurate positioning of the substrate relative to the bonding heads 122. The stage position encoder may be: a laser optical interferometer position measurement system; an ultrasonic distance measurement system; a capacitive displacement measurement system; optical position encoder system; and other methods of measuring the position of an object with sub-micron resolution. Each of the bonding head stages 222b may include a bonding head position encoder that is similar to the stage position encoder. In an embodiment, the contact measurement steps S308(a, b) may be performed again after the position adjustment step S310, these steps may be repeated until the measurements are within an alignment threshold. In an alternative embodiment, the contact measurement steps S308(a, b) are performed only once for each bonding step.

The bonding method 300 may include a bonding step S312 in which one or more bonding heads 122 are brought towards the substrate chuck 108. Each of the chiplet stages 222b may include one or more actuators which move each chiplet chuck 222a towards the substrate chuck 110 until each chiplet 102 held by a bonding head touches the substrate 104. The bonding step S312 is the step in which the chiplet is brought into contact with the substrate by the bonding head and is just one part of an overall bonding process.

If the bonding method 300 is a hybrid bonding method, then the bonding surfaces 136 (chiplet bonding surfaces 136a and substrate bonding surface 136b) are activated prior to the bonding step S312. The chiplet bonding surfaces 136a may be activated while the chiplets are on the bonding heads 122. The chiplet bonding surfaces 136a may be activated while the chiplets are on the transfer heads 120. The chiplet bonding surfaces 136a may be activated while the chiplets are on the transfer substrate 106 while it is on the transfer chuck 110. The chiplet bonding surfaces 136a may be activated while the chiplets are on the transfer substrate 106 while it is on the transfer chuck 110. The chiplet bonding surfaces 136a may be activated prior to the first loading step S302a. The substrate bonding surface 136b the substrate 104 may be activated while the substrate 104 is on the substrate chuck 108. The substrate bonding surface 136b may be activated prior to the second loading step S302b.

Activating the bonding surfaces 136 may include rinsing the bonding surfaces 136 with deionized water and exposing the bonding surfaces 136 to a plasma. Other well-known methods may be used for preparing the bonding surfaces 136 so that dangling bonds are created on the bonding surfaces 136.

After the bonding step S312, the transfer substrate may be checked in a transfer substrate checking step S314. The transfer substrate checking step S314 may include the processor 130 checking information about the transfer substrate 106 in memory 132 to determine how many chiplets 102 were on the transfer substrate 106 that were to be bonded and how many were removed in subsequent transfer steps. If the answer is yes and the transfer substrate is empty of chiplets that are to be transferred, then the processor 130 will send instructions for the transfer substrate to be removed from the bonding system 100 in a first unloading step S316. After the first unloading step S316 the bonding method 300 returns to first loading step S302a unless there are no more chiplets to be bonded in which case the bonding method 300 ends. If the transfer substrate 106 is not empty of chiplets to be bonded, then the bonding method 300 returns to transfer step S306.

Also after the bonding step S312 the substrate 102 is checked in a substrate checking step S318. The substrate checking step S318 may include the processor 130 checking information about the substrate 104 in memory 132 to determine how many bonding locations were on the substrate 104 that were to be bonded to and how many of those bonding locations already have chiplets bonded to them in bonding step S312. If the answer is yes and there are no more empty bonding locations, then the processor 130 will send instructions for the substrate 104 to be removed from the bonding system 100 in a second unloading step S320. After the second unloading step S320 the bonding method 300 returns to second loading step S302 unless there are no more chiplets to be bonded in which case the bonding method 300 ends.

After the second unloading step S320, if the substrate is being bonding with a hybrid bonding method, then the substrate 104 is subjected to a heating step S322. During the heating step S322 the substrate is heated which causes the metal interconnect contacts 202 to expand relative to the bonding surface 136 forming electrical connections between the chiplets 102 and the substrate 104. The heating step S322 may be performed at 200° C. to 300° C. In an embodiment, the heating step S322 may be performed at a higher temperature than the bonding step S312. The product substrate may then be subjected to additional bonding method 300 to attach additional chiplets to the substrate. After the heating step S322 the substrate may be subjected to additional semiconductor processing steps, such as: singulation, testing, encapsulation, etc., which are used to produce a plurality of articles from the substrate.

### Alignment System

The bonding system 100 includes an alignment system 124. The upward facing alignment system 124a, the downward facing alignment system 124b, or a single alignment system that looks both up and down are all examples of the alignment system 124 which may be used in the bonding system 300. The alignment system 124 may be a microscope 400, include a microscope or be connected to a microscope. The microscope 400 may include one or more internal positioning systems for adjusting positions of internal components of the microscope and may also be mounted onto an external positioning system for moving the microscope 400.

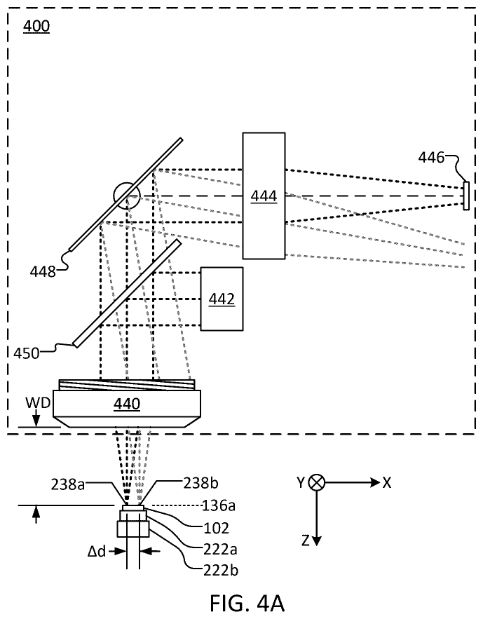

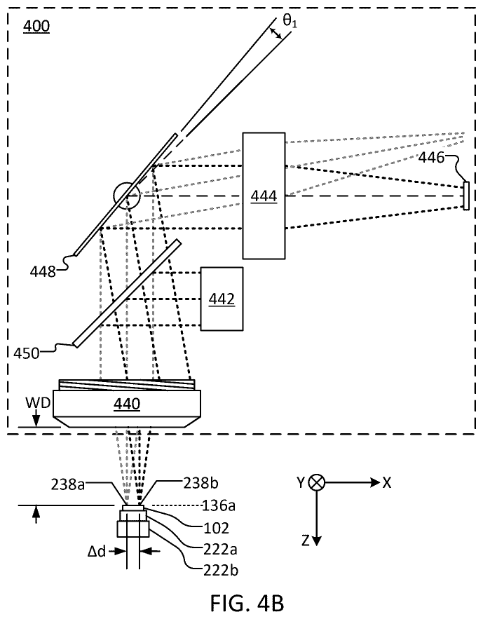

The microscope 400 is configured to generate images of objects held by a chuck (bonding head chip chuck 222a and/or substrate chuck 108) as illustrated in FIGS. 4A-B. The images generated by the microscope 400 may include interconnect contacts 105 or alignment features. The object being imaged by the microscope 400 may be a chiplet 102 held by chiplet chuck 222a or substrate 104 held by the substrate chuck 108.

The microscope 400 is configured to be in at least two different states. When the microscope 400 is in a first state, as illustrated in FIG. 4A, the microscope will guide light (black dotted lines) from a first region 238a of the object held by a chuck to a sensor 446. The sensor 446 generates a first image of the first region 238a. The sensor 446 transmits the first image to one or more processors 130. When the microscope 400 is in a second state, as illustrated in FIG. 4B, the microscope will guide light (black dotted lines) from a second region 238b of the object held by a chuck to the sensor 446. The sensor 446 generates a second image of the second region 238b. The sensor 446 transmits the second image to one or more processors 130. The grey lines in FIGS. 4A-B show the light coming from the regions that are not imaged by the microscope depending on the state of the microscope. The microscope 400 may include the sensor 446 or the sensor 446 may be part of an imaging device that is mounted onto the microscope 400. The imaging device may be one of: a CMOS sensor, a CCD sensor, a EMCCD sensor, a SWIR sensor, a microbolometer sensor array, or a digital camera. The imaging device may be a monochrome imaging device. The imaging device may be for example a 5 megapixel camera such as a CI-5MGMCL from Canon Inc., of Tokyo Japan. The imaging device may generate an image. The image may be in the form of digital signals that are transmitted to a processor or stored directly in computer readable memory.

Changing the state of the microscope 400, changes the center of the region of light guided from the object to the sensor 446. The microscope 400 may be positioned with a positioning system above a chuck so that a front focal plane coincides with a bonding surface 136 of the object held by the chuck. The front focal plane of the microscope is adjusted to be within a depth of focus of the bonding surface 136 of the object that is held on the chuck when the sensor 446 generates images. A positioning system may be used to move the chuck and the microscope relative to each other. The positioning system may include the chiplet stage 222b, the substrate stage 114, and/or the carriage 116.

In an embodiment, the microscope 400 is positioned relative to a chiplet bonding surface 136a of a chiplet 102 held by a chiplet chuck 222a. The chiplet 102 includes a chiplet set of interconnect contacts 202a. When the microscope 400 is in the first state, the microscope 400 guides light from a first subset of the plurality of chiplet bonding pads 238a to the sensor 446. When the microscope 400 is in the second state, the microscope 400 guides light from a second subset of the plurality of chiplet bonding pads 238b to the sensor 446 as illustrated in FIGS. 4A-B. When the microscope 400 is in either of the first state and the second state the relative position of the microscope 400 to the chiplet chuck 222a does not change, the sensor 446 does not move, but the rotatable optical element 448 does change. The microscope 400 is configured to generate a first image of the first subset of the plurality of chiplet bonding pads 238a with the microscope in the first state. The microscope 400 is also configured to generate a second image of the second subset of the plurality of chiplet bonding pads 238b with the microscope 400 in the second state. The sensor 446 of the microscope generates the first image and the second image and sends them to a processor, a controller or stores them in memory.

The microscope 400 may include an illuminator 442 configured to illuminate the bonding surface 136. The illuminator may be a ring light, a fiber optic illuminator, a halogen bulb, an LED, an array of LEDs, or a Laser. The illuminator may include wavelength filter. The illuminator may be a polarized light source and/or include a polarizer. The illuminator may supply light with an illumination wavelength with a narrow wavelength range or multiple wavelength ranges. The wavelength of the illuminator may be selected to provide contrast between the interconnect contacts 202 and the rest of the bonding surface 136 (for example 755 nm).

The microscope 400 may include a first optical subsystem 440 configured to receive light from the first chiplet 102. The first optical subsystem 440 is configured to receive light from both the first subset of the plurality of chiplet bonding pads 238a and the second subset of the plurality of chiplet bonding pads 238b. The first optical subsystem 440 may be an infinity corrected objective configured to work at an illumination wavelength from the illuminator 442. The first optical subsystem 440 may be a bright field, long distance, infinity-corrected objective such as M Plan Apo HR 10×, Model No. 378-788-4 from Mitutoyo Corporation of Kawasaki-shi, Kanagawa-ken, Japan. The first optical subsystem may include one or more lens which are arranged relative to each other to have: a first focal length f₁, a first front focal length f_{1,f}, and a first back focal length f_{1,b}. The first optical subsystem 440 may include an infinity corrected objective and one or more relay lens to form a conjugate focal plane that is conjugate with the back focal plane of the infinity corrected objective.

The microscope 400 may include a second optical subsystem 444 that is configured to transmit light towards the sensor 446. The second optical subsystem 444 may include one or more lenses which are arranged relative to each other to have: a second focal length f₂, a second front focal length f_{2,f}, and a second back focal length f_{2,b}. The second optical subsystem 444 is arranged relative to the first optical subsystem 440 based on the first back focal length f_{1,b} of the first optical subsystem 440 and the second front focal length f_{2,f} of the second optical subsystem 444. The second optical subsystem 444 is arranged relative to the sensor 446 based on the second back focal length f_{2,b}. The second optical subsystem 444 may be a commercially available optical assembly that has been specifically designed to work with the first optical subsystem 440 to achieve the desired magnification (1×, 5×, 10×, 20×, 50×, 100×) and desired imaging resolution. For example, an infinity-corrected objective are typically designed to work with a tube lens such as the tube lens MT-1, Model No. 970208 from Mitutoyo Corporation of Kawasaki-shi, Kanagawa-ken, Japan.

The microscope 400 may include a rotatable optical element 448 located between the first optical subsystem 440 and the second optical subsystem 444 configured to be at a first angle θ₁ when the microscope is in the first state and configured to be at a second angle θ₂ when the microscope is in the second state. The rotatable optical element 448 may be an optical element (mirror, window, etc.) mounted on a servomotor or tipping and tilting motion stage. The rotatable optical element 448 may be a front surface mirror mounted for example on a Tip/Tilt Platform, Model No. S-330.8SH from 4 Physik Instrumente (PI) GmbH & Co. KG. of Karlsruhe, Germany. The rotatable optical element 448 may be two different optical elements, a first rotatable optical element mounted that rotates around a first axis, and a second rotatable optical element mounted that rotates around a second axis orthogonal to the first axis. The rotatable optical element 448 may have rotation range of at least 0.1°, 1°, 3°, 5°, 10° or 20°. For small rotations the optical distortion introduced by the lenses will be small. Larger rotation angles can introduce larger optical distortions. In an embodiment, images obtained by the sensor 446 are corrected using lens distortion correction techniques using calibration images.

The microscope may include a beam combiner 450 such as cube beamsplitter, a plate beamsplitter, or a half silvered mirror. The beam combiner 450 may be positioned to receive light from the illuminator 442 and guide that light towards an exit pupil of the first optical subsystem

In an embodiment, the first optical subsystem 440 has a first acceptance angle that allows the first optical subsystem 440 to transmit light received from both the first subset of the plurality of chiplet bonding pads 238a and the second subset of the plurality of chiplet bonding pads 238b towards the rotatable optical element 448 while the first optical subsystem 440 is at a working distance WD from a chiplet 102 mounted on the chiplet chuck 222a. The sensor 446 is also located at a second back focal plane of the second optical subsystem while the microscope 400 is in the first state and the second state. The sensor 446 may receive light representative of the first image and not the second image. The microscope 400 may include a first aperture stop between the rotatable optical element 448 and the sensor 446. The first aperture stop may be a part of the second optical subsystem 444 or the sensor 446. The sensor 446 receives light representative of the first image while not receiving light representative of the second image when the microscope 400 is in the first state. The sensor 446 receives light representative of the second image while not receiving light representative of the first image when the microscope 400 is in the second state.

In an embodiment, a front focal plane of the first optical subsystem is within a depth of focus distance from and parallel to an average plane of the interconnect contacts 202 when held by the chuck.

In an embodiment, a back focal plane of the second optical subsystem 444 is within a depth of focus distance from and parallel to a plane of a sensing surface of the sensor 446.

In an embodiment, a center of rotation of the rotatable optical element is within a threshold distance from a back focal plane of the first optical subsystem. The threshold distance may be between 1 mm and 0.01 mm. In cases where the back focal plane of the first optical subsystem 440 is physically inside the first optical system physical envelope, the back focal plane can be accessed using a 4F optics system (a type of afocal system) with magnification of one and the rotatable optical element 448 could be placed with its center at this relayed location. An example of a 4F optical system include a first relay lens and a second relay lens. The first relay lens is placed so that its front focal plane is coincident with the back focal plane of the first optical subsystem. The second relay lens is placed so that its front focal plane is coincident with the back focal plane of the first relay lens. The rotatable optical element 448 is then placed at the back focal plane of the second relay lens. The rotatable optical element 448 is thus located at a conjugate focal plane of the first optical subsystem 440.

In an embodiment, the center of rotation of the rotatable optical element is within the threshold distance from a front focal plane of the second optical subsystem.

### Second Embodiment of the Alignment System

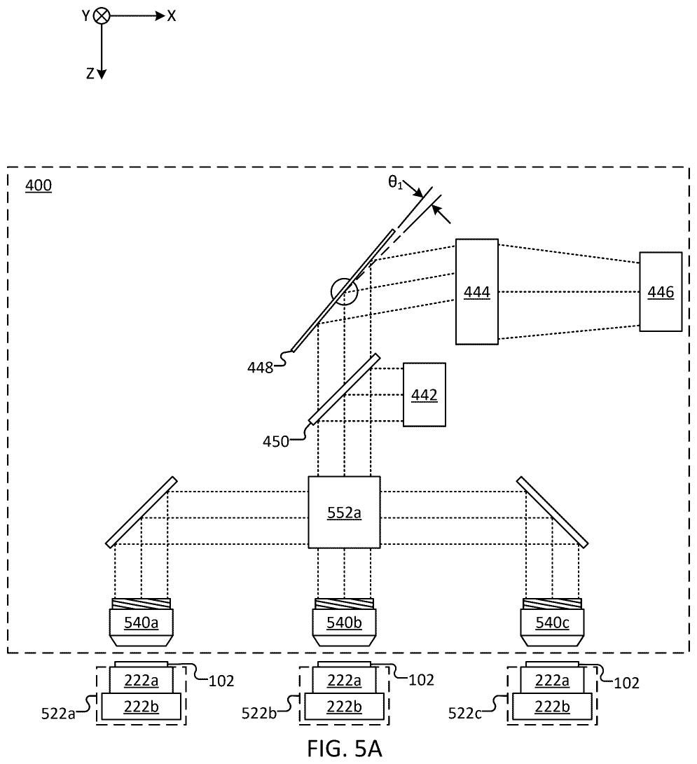

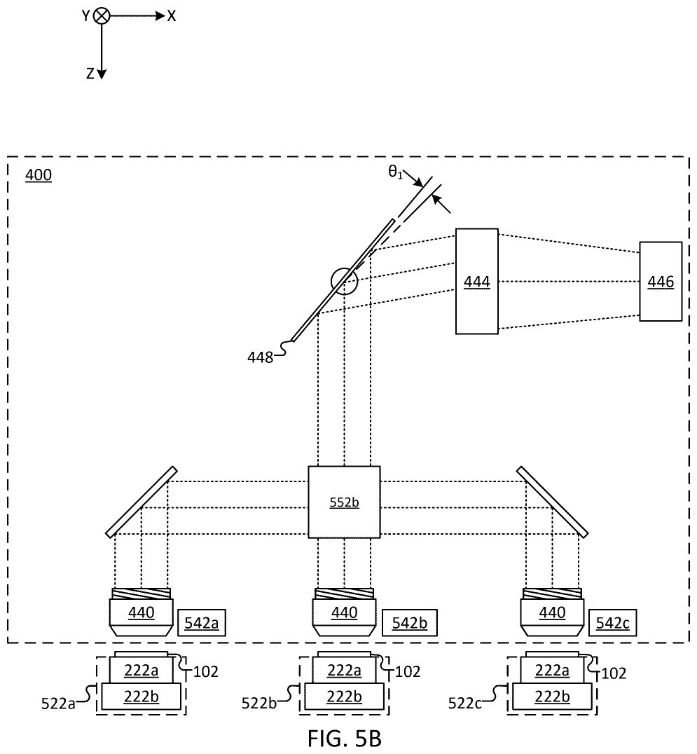

In an embodiment, the first optical subsystem includes multiple subordinate optical systems 554, one for each bonding head as illustrated in FIGS. 5A-B. For example, FIGS. 5A-B illustrates a system with three bonding heads and three corresponding subordinate optical system. A first subordinate optical system 540a is configured to receive light from a first sensing region above the first bonding head 522a. The first sensing region includes a first chiplet 102 mounted on the first bonding head 522a. A second subordinate optical system 540b is configured to receive light from a second sensing region above the second bonding head 522b. The second sensing region includes a second chiplet 102 mounted on the second bonding head 522b. A third subordinate optical system 540c is configured to receive light from a third sensing region above the third bonding head 522c. The third sensing region includes a third chiplet 102 mounted on the third bonding head 522c. An embodiment may include one or more additional subordinate optical systems each configured to receive light from an additional sensing region above an additional bonding head. The additional sensing region includes an additional chiplet 102 mounted on the additional bonding head.

An embodiment may include an optical combiner 552 configured to: receive light from multiple subordinate optical systems. The optical combiner 552 is configured to transmit light to the rotatable optical element 448. The optical combiner 552 may be 1×N optical switch 552a that includes optical elements such as movable mirrors or other optical components that change how light is guided between N optical ports and 1 combined optical port. The optical switch may be in a first switching state in which light is guided between the beam combiner 450 and the first subordinate optical system 540a. The optical switch 552a may be in a second switching state in which light is guided between the beam combiner 450 and the second subordinate optical system 540b. The optical switch may be in a third switching state in which light is guided between the beam combiner 450 and the third subordinate optical system 540c. The optical switch may be in an additional switching state in which light is guided between the beam combiner 450 and the additional subordinate optical system 540c.

An alternative embodiment of the microscope in FIG. 5A is illustrated in FIG. 5B the illuminator and is replaced with an illumination system that includes an illuminator for each bonding head. The optical combiner may be a beam combiner 552b that receives light from all the sensing regions above the bonding heads and guides the received light towards the rotatable optical element. When the illumination system is in a first illumination state, the first illuminator 542a is on and the other illuminators are off. When the illumination system is in a second illumination state, the second illuminator 542b is on and the other illuminators are off. When the illumination system is in a third illumination state, the third illuminator 542a is on and the other illuminators are off. There may be additional illuminators, additional illumination states that correspond with illuminating additional bonding heads.

### Third Embodiment of the Alignment System

As illustrated in FIGS. 4A-B, when the rotatable optical element 448 is rotated optical image guided to the sensor 446 is not necessarily guided to the same spot on the sensor 446. The rotatable optical element 448 may introduce a lateral shift at the sensor 446. Depending on the focal length of the second optical subsystem and the angle of rotation this shift may be insignificant. When the shift is large, it may be advantageous to introduce a lateral shifting optical element that performs a compensatory lateral shift to the optical beam between the rotatable optical element 448 and the second optical subsystem 444. The lateral shifting optical element may be an optical element (lens, window, etc.) mounted on a servomotor or tipping and tilting motion stage. The lateral shifting optical element may be an anti-reflection coated window mounted, for example, on a Tip/Tilt Platform, Model No. S-330.8SH from 4 Physik Instrumente (PI) GmbH & Co. KG. of Karlsruhe, Germany. The lateral shifter may also be a purpose-built beam shifter such as the BSW-20 from Optotune Switzerland AG of Dietikon, Switzerland.

### Alignment Method

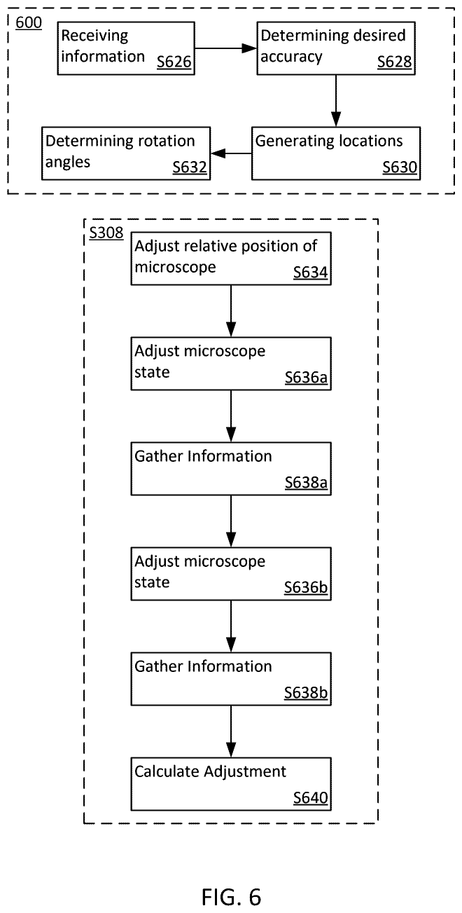

The contacts position measuring step S308a and the substrate contacts position measuring step S308b may be done using the same contacts measuring step S308 the details of which are described in FIG. 6. Prior to performing the contacts measuring step S308 an alignment setup process 600 is performed which varies depending on the arrangement of the interconnect contacts. The alignment setup process 600 generates information that is then used in the contacts measuring step S308.

The alignment setup process 600 may include a receiving step S626. The receiving step S626 may include the processor(s) 130 receiving interconnect information about the interconnect contacts 202 including information about both the chiplet set of interconnect contacts 202a and the substrate set of interconnect contacts 202b. The interconnect information includes the position of each of the interconnect contacts relative to the edges of the bonding surface. The interconnect information may be received over a network, from an internal database or generated using one or more of: the upward imaging system 124a; the downward imaging system 124b; upward facing alignment system 124a; and the downward facing alignment system 124b.

The alignment setup process 600 may include a desired accuracy determination step S628. The desired accuracy is the measurement accuracy/uncertainty allowable to achieve the desired die placement accuracy. The desired accuracy determination step S628 may include receiving a desired accuracy ε from an external server, from memory, or from a GUI presented to an operator. The desired accuracy determination step S628 may include generating a desired accuracy based on the interconnection information. The desired accuracy ε may be a fraction (0.5, 0.1, 0.01, 0.005, 0.001) of the size of individual interconnect contact. The desired accuracy ε may include multiple components for example ε≡{εₓ, ε_{y}, ε_{θ}}. The cartesian components of the desired accuracy (εₓ, ε_{y}) may be based on the size of individual interconnect contacts. The angular component of the desired accuracy (ε_{θ}) may be based on the extent of the set of interconnect contacts.

The alignment setup process 600 may include generating locations step S630. The generating locations step S630 may include generating a first inspection region at a first location (x₁, y₁) and a second inspection region in a second location (x₂, y₂) on the bonding surface based on the information about the interconnect contacts and properties of the optical microscope 400. The processor 140 may determine the size of the inspection regions for example based on: the desired accuracy (εₓ, ε_{y}), resolution of the sensor 446, the magnification of the microscope 400, and the resolution of the image position identification method. The generating locations step S630 may include receiving a size of the inspection regions may include receiving a size of the inspection regions from an external server, from memory, or from a GUI presented to an operator.

The generating locations step S630 may include the processor 140 identifying two inspection regions on the bonding surface that are a distance Δr(Δx, Δy) apart. When the two inspection regions are used for determining the angular position of the interconnect contacts, then the minimum distance apart is related to the angular component of the desired accuracy (ε_{θ}). The distance Δr should be greater than a threshold that is a function G of the desired accuracy (ε_{θ}) and as described in equation (1a) below.

$$Δ r * {ε}_{θ} \geq \sqrt{{ε}_{x}^{2} + {ε}_{y}^{2}} \qquad ( 1 a )$$

Alternatively, given the desired accuracy (εₓ, ε_{y}) in translation and a given maximum size of the die with a maximum diagonal of size, Ar, the finest achievable accuracy (ε_{θ}) can be determined by the following equation (1b):

$${ε}_{θ} \geq \frac{\sqrt{{ε}_{x}^{2} + {ε}_{y}^{2}}}{Δ r} \qquad ( 1 b )$$

Each of the inspection regions should include unique arrangements of interconnect contacts within an imaging region. Examples of unique arrangements are: arrangements that include a corner; arrangements with one or more missing interconnect contacts in an array; arrangements that include a non-interconnect feature that is not an interconnect contact that is aligned with the set of interconnect contacts.

The alignment setup process 600 may include a determining rotation angles step S632. The determining rotation angles step S632 may include determining a desired relative position (x₀, y₀) of the bonding surface coincident with an optical axis of the first optical subsystem 440. In the example illustrated in FIGS. 4A-B the desired relative position of the chiplet (x₀, y₀) is coincident with the first location (x₁, y₁). In the example illustrated in FIGS. 5A-B the desired relative position (x₀, y₀) of each chiplet is aligned with the center of each chiplet. The desired relative position (x₀, y₀) may be the average of the locations of the inspection regions which minimizes the optical distortions due off-center imaging. The determining rotation angles step S632 may include a coordinate transformation relative to the desired relative position (x₀, y₀) of the bonding surface. The processor 130 may calculate rotation angles (θ_{x,1}, θ_{y,1}, θ_{x,2}, θ_{y,2}) based on the properties of the first optical subsystem. For example, equation (2) below describes one method of determining the rotation angles. Optical simulation methods may also be used for determining the rotation angles.

$${θ}_{x , 1} = {tan}^{- 1} ( \frac{{x}_{1} - {x}_{0}}{2 {f}_{1 , f}} ) ≅ \frac{{x}_{1} - {x}_{0}}{2 {f}_{1 , f}} \qquad ( 2 )$$

$${θ}_{y , 1} = {tan}^{- 1} ( \frac{{y}_{1} - {y}_{0}}{2 {f}_{1 , f}} ) ≅ \frac{{y}_{1} - {y}_{0}}{2 {f}_{1 , f}}$$

$${θ}_{x , 2} = {tan}^{- 1} ( \frac{{x}_{2} - {x}_{0}}{2 {f}_{1 , f}} ) ≅ \frac{{x}_{2} - {x}_{0}}{2 {f}_{1 , f}}$$

$${θ}_{y , 2} = {tan}^{- 1} ( \frac{{y}_{2} - {y}_{0}}{2 {f}_{1 , f}} ) ≅ \frac{{y}_{2} - {y}_{0}}{2 {f}_{1 , f}}$$

The contacts position measuring step S308 may include a microscope positioning step S634 in which the bonding surface and the microscope 400 are moved relative to each other so that the bonding surface is at the desired relative position (x₀, y₀). The microscope positioning step S634 may include the processor sending instructions to one or more of: the substrate stage 114; the chiplet stage 222b; and a microscope positioning system. The microscope positioning system may include one or more actuators or stages such as voice coil motors, piezoelectric motors, linear motors, nut and screw motors, piezo-actuated stages, brushless DC motor stages, DC motor stages stepper motors; or other systems that can move the microscope relative to the bonding surfaces the contacts position measuring step S308.

The contacts position measuring step S308 may include a first microscope state adjustment step S636a. The first microscope state adjustment step S636a may include adjusting the state of the microscope to be in a first state. When the microscope 400 is in the first state the microscope 400 will guide light from the first subset of the plurality of chiplet bonding pads 238a to the sensor 446. Adjusting the state of the microscope 400 may include moving an optical component within the microscope 400. For example, the processor 130 may send instructions to a rotatable optical element 448. The processor may send instructions to ensure that the rotatable optical element 448 is at the rotation angles (θ_{x,1}, θ_{y,1}) determined in S632. These rotation angles are set relative to a default state.

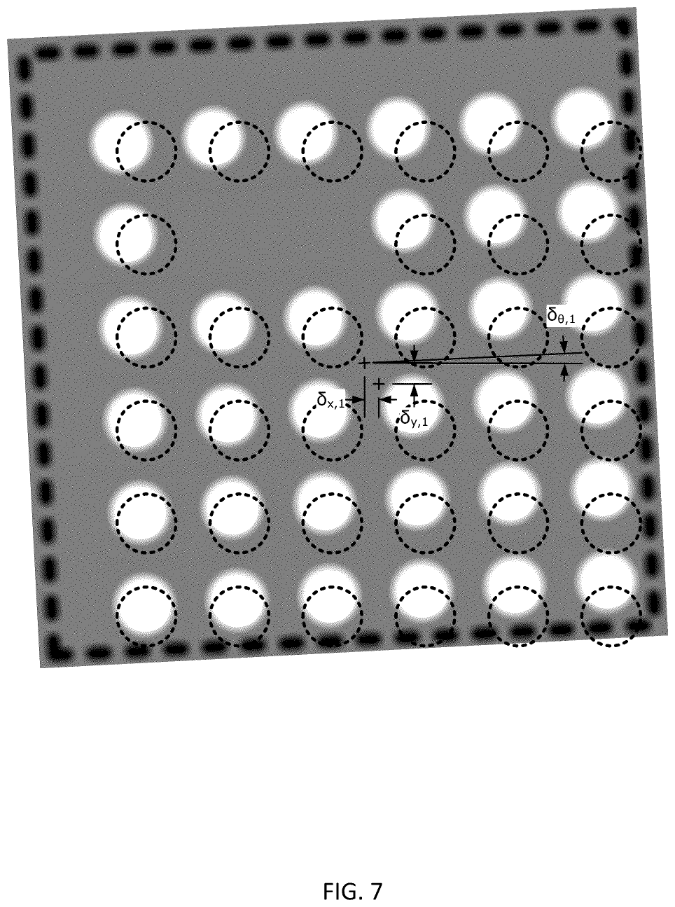

The contacts position measuring step S308 may include a first information gathering step S638a. The first information gathering step S638a may include the sensor 446 sending image information to a processor 130 after the microscope has stabilized in the first state. The processor 130 may then use a digital image correlation method or a registration method such as the one described in B. Srinivasa REDDY, B. N. CHATTERJI, An FFT-Based Technique for Translation, Rotation, and Scale-Invariant Image Registration, IEEE Transactions on Image Processing, 5(8):1266-1271 August 1996, IEEE, Piscataway NJ which is hereby incorporated by reference. FIG. 7 is an illustration of an image relative to a reference illustrated as dashed circles. The processor may calculate a first set of image offsets δ₁ that include: a first x-coordinate image offset δ_{x,1}; a first y-coordinate image offset δ_{y,1}; and possibly a first θ-coordinate image offset δ_{θ,1}.

The contacts position measuring step S308 may include a second microscope state adjustment step S636b similar to the first microscope state adjustment step S636b except that the microscope is adjusted to be in the second state. When the microscope 400 is in the second state the microscope 400 will guide light from the second subset of the plurality of chiplet bonding pads 238b to the sensor 446. The processor may send instructions to ensure that the rotatable optical element 448 is at the rotation angles (θ_{x,2}, θ_{y,2}) determined in S632.

The contacts position measuring step S308 may include a second information gathering step S638b that is similar to the first information gather step S638a. The second information gathering step S638a may include the sensor 446 sending image information to a processor 130 after the microscope has stabilized in the second state. The processor may calculate a second set of image offsets δ₂ that include: a second x-coordinate image offset δ_{x,2}; a second y-coordinate image offset δ_{y,2}; and possibly a second θ-coordinate image offset δ_{θ,2}. The second set of image offsets δ₂ may be similar to the first set of image offsets except they are relative to a second reference image.

The contacts position measuring step S308 may include calculating the suggested adjustment values k which is sent to one or both of the chiplet stage 222b and the substrate stage 114. The suggested adjustment values k may include: an x-coordinate suggested adjustment value k_{0,x}; a y-coordinate suggested adjustment value k_{0,y}; and an θ-coordinate suggested adjustment value k_{θ}. The suggested adjustment values k may be calculated according to equations (3) below:

$${e}_{x} = [ \begin{matrix}{δ}_{x 1} \\ {δ}_{x 2}\end{matrix} ] = [ \begin{matrix}1 & {y}_{1} \\ 1 & {y}_{2}\end{matrix} ] [ \begin{matrix}{k}_{0 , x} \\ {k}_{1 , x}\end{matrix} ] + {∈}_{x} ; \qquad ( 3 )$$

$${e}_{y} = [ \begin{matrix}{δ}_{y 1} \\ {δ}_{y 2}\end{matrix} ] = [ \begin{matrix}1 & {x}_{1} \\ 1 & {x}_{2}\end{matrix} ] [ \begin{matrix}{k}_{0 , y} \\ {k}_{1 , y}\end{matrix} ] + {∈}_{y} ;$$

$${k}_{θ} = \frac{{k}_{1 y} - {k}_{1 x}}{2}$$

The above equations describe the arrays of errors (e_{y}, e_{y}) that describe the array of measured x-errors, (δₓᵢ) and y-errors, (δ_{yi}) for i-th image. The above equations can be solved using a least squares solver to determine the pure translation errors in X & Y directions: k_{0,x} and k_{0,y} as well as the pure rotation error k_{θ}, to minimize the residual errors, ϵₓ and ϵ_{y}. This method of calculating pure translation and pure rotation is extensible to multiple errors (δs) obtained from multiple images (i) at distinct locations on the chiplet.

Once the suggested adjustment values k are determined, these values are used during the position adjustment step S310. If the contact measuring step is repeated for a particular chiplet then the microscope positioning step S634 can be skipped.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A bonding system configured to bond a first chiplet to a first destination site, wherein the first chiplet has a plurality of chiplet bonding pads, wherein the first destination site has a first plurality of destination bonding pads, the bonding system comprising:
a first bonding head configured to hold the first chiplet;
a microscope configured to:
generate a first image of a first subset of the plurality of chiplet bonding pads with the microscope in a first state; and
generate a second image of a second subset of the plurality of chiplet bonding pads with the microscope in a second state;
a processor configured to estimate a first orientation of the first chiplet based on the first image and the second image;
a positioning system configured to adjust the first chiplet and the first destination site relative to each other based on the first orientation; and
wherein the first bonding head is configured to bond the first chiplet to the first destination site.

2. The bonding system of claim 1, wherein the microscope comprises:
a sensor;
a first optical subsystem configured to receive light from the first chiplet;
a second optical subsystem configured to transmit light towards the sensor; and
a rotatable optical element located between the first optical subsystem and the second optical subsystem configured to be at a first angle when the microscope is in the first state and configured to be at a second angle when the microscope is in the second state.

3. The bonding system of claim 2, wherein:
a first acceptance angle of the first optical subsystem while at a working distance from the first chiplet receives light from both the first subset of the plurality of chiplet bonding pads and the second subset of the plurality of chiplet bonding pads; and
the sensor is located at a focal plane of the second optical subsystem while the microscope is in the first state and the second state;
the sensor receives light representative of the first image while not receiving light representative of the second image when the microscope is in the first state; and
the sensor receives light representative of the second image while not receiving light representative of the first image when the microscope is in the second state.

4. The bonding system of claim 2, wherein a front focal plane of the first optical subsystem is within a depth of focus distance from and parallel to an average plane of the plurality of chiplet bonding pads when held by the first bonding head.

5. The bonding system of claim 2, wherein a focal plane of the second optical subsystem is within a depth of focus distance from and parallel to a plane of the sensor.

6. The bonding system of claim 2, wherein a center of rotation of the rotatable optical element is within a threshold distance from a back focal plane of the first optical subsystem.

7. The bonding system of claim 2, wherein a center of rotation of the rotatable optical element is within a threshold distance from the front focal plane of the second optical subsystem.

8. The bonding system of claim 2, wherein the first optical subsystem includes:
a first subordinate optical system configured to receive light from a first sensing region above the first bonding head;
a second subordinate optical system configured to receive light from a second sensing region above a second bonding head;
an optical combiner configured to:
receive light from the first subordinate optical system and the second subordinate optical system; and
transmit light to the rotatable optical element.

9. The bonding system of claim 8, wherein the optical combiner includes one or more of:
an illumination system that illuminates both the first sensing region and the second sensing region; and
an optical switch that alternatively receives light from either the first sensing region and the second sensing region; and guides the received light towards the rotatable optical element.

10. The bonding system of claim 8, wherein the optical combiner includes one or more of:
an illumination system that alternatively illuminates the first sensing region and the second sensing region; and
a beam combiner that receives light from both the first sensing region and the second sensing region; and guides the received light towards the rotatable optical element.

11. A bonding method employing a bonding system configured to bond a first chiplet to a first destination site, wherein the first chiplet has a plurality of chiplet bonding pads, wherein the first destination site has a first plurality of destination bonding pads, the bonding method comprising:
holding the first chiplet with a first bonding head;
generating a first image of a first subset of the plurality of chiplet bonding pads with a microscope in a first state;
generating a second image of a second subset of the plurality of chiplet bonding pads with the microscope in a second state;
estimating a first orientation of the first chiplet based on the first image and the second image;
adjusting the first chiplet and the first destination site relative to each other with a positioning system based on the first orientation; and
bonding the first chiplet to the first destination site with the bonding head.

12. The bonding method of claim 11, further comprising:
switching the microscope from the first state to the second state by rotating a rotatable optical element;
wherein the optical element is positioned between a first optical subsystem and a second optical subsystem;
wherein the first optical subsystem is configured to receive light from the first chiplet;
wherein the second optical subsystem is configured to transmit light towards the sensor.

13. The bonding method of claim 12, further comprising:
receiving, by the first optical subsystem while at a working distance from the first chiplet, light from both the first subset of the plurality of chiplet bonding pads and the second subset of the plurality of chiplet bonding pads; and
receiving, by the sensor located at a focal plane of the second optical subsystem while the microscope is in the first state. light representative of the first image and not the second image.

14. The bonding method of claim 12, further comprising:
adjusting a relative position of the first bonding head and a front focal plane of the first optical system so that an average plane of the plurality of chiplet bonding pads when held by the first bonding head is within a depth of focus distance of the first optical system.

15. The bonding method of claim 12, further comprising:
adjusting a relative position of a focal plane of the second optical system to be within a depth of focus distance from and parallel to a plane of the sensor.

16. The bonding method of claim 12, further comprising:
receiving light from a first sensing region above the first bonding head with a first subordinate optical system of the first optical subsystem;
receiving light from a second sensing region above a second bonding head with a second subordinate optical system of the first optical subsystem;
receiving light from the first subordinate optical system and the second subordinate optical system with an optical combiner of the first optical subsystem; and
transmitting light to the rotatable optical element with the optical combiner.

17. The bonding method of claim 12, further comprising:
switching between illuminating the first sensing region and the second sensing region with an illumination system of the optical combiner;
receiving light from both the first sensing region and the second sensing region with a beam combiner of the optical combiner; and
guiding the received light the received light towards the rotatable optical element with the beam combiner.

18. The bonding method of claim 12, further comprising:
illuminating both the first sensing region and the second sensing region with an illumination system of the optical combiner;
receiving light from both the first sensing region and the second sensing region with an optical switch of the optical combiner; and
switching between guiding light from either the first sensing region and the second sensing region towards the rotatable optical element with the beam combiner with the optical switch.

19. The bonding method of claim 11, further comprising:
estimating a first x-y shift of the first image relative to a first reference image;
estimating a second x-y shift of the second image relative to a second reference image;
wherein estimating the first orientation includes estimating a rotation error of the first chiplet based on the first x-y shift and the second x-y shift;
holding a destination substrate having a destination site; and
adjusting a relative position of the chiplet and the destination site based on both the first x-y shift, second x-y shift, and the rotation error.

20. The bonding method of claim 11, wherein the first and second subsets of the plurality of chiplet bonding pads each include a unique arrangement of chiplet bonding pads relative to the plurality of chiplet bonding pads.
